(19) United States
(12) Patent Application Publication
(10) Pub. No.: US 2026/0258545 A1
(43) Pub. Date: Sep. 3, 2026

(54) WIRE ROD DEPOSITION SYSTEM

(71) Applicant: MARU L&C CO., LTD., Daegu (KR)

(72) Inventor: Dong Jin Kim, Daegu (KR)

(73) Assignee: MARU L&C CO., LTD., Daegu (KR)

(21) Appl. No.: 18/995,711

(22) PCT Filed: Jul. 5, 2024
(86) PCT No.: PCT/KR2024/009532

§ 371 Date: Jan. 16, 2025

(30) Foreign Application Priority Data
Jul. 7, 2023 (KR) 10-2023-0088549

(51) Int. Cl. C23C 14/56; C23C 14/02; C23C 14/34; C23C 14/58

(52) U.S. Cl. CPC C23C 14/562; C23C 14/02; C23C 14/3407; C23C 14/5806

(57) ABSTRACT

The present invention relates to a wire rod deposition system including a plurality of roller parts around which a wire rod is wound to move and which are axially length-adjustable, a heater part heating the wire rod passing the roller parts, a cathode part providing a deposition material to the wire rod, and a cooling part cooling the wire rod, and in this way, the wire rod is heated by the heater part and is deposited by moving while wound around the plurality of roller parts, and the roller parts are axially length-adjustable even when heated by the heater part, and accordingly, it is possible to stably support the wire rod.

### TECHNICAL FIELD

The present invention relates to a wire rod deposition system, and more particularly, to a wire rod deposition system that can obtain excellent thin film quality as materials reach a surface of a wire rod and have a certain direction in a set area.

### BACKGROUND ART

Generally, as anticipation of the commercialization of superconducting application technologies using high-temperature superconductors increases, research on the development of high-temperature superconducting wire rods is being actively conducted worldwide.

Methods of manufacturing high-temperature superconducting wire rods include the first-generation high-temperature superconducting wire rod manufacturing method using the powder in tube (PIT) process, which involves filling a silver (Ag) pipe with a precursor powder to process the precursor powder, and the second-generation high-temperature superconducting wire rod manufacturing method of manufacturing a high-temperature superconducting wire rod referred to as a coated conductor (CC) in technical terms.

The CC, which is the second-generation high-temperature superconducting wire rod, is being researched and developed by many research institutes and companies around the world, has various manufacturing methods, and has a more complex multi-layer structure than the first-generation high-temperature superconducting wire rod.

Conventionally, there is a problem in that a roller around which a wire rod is wound is damaged in a process of heating the wire rod to a high temperature, and defects in wire rod deposition occur frequently. Therefore, there is a need to address this.

The related art of the present invention is disclosed in Korean Patent Registration No. 10-0910613 (Date of Registration: Jul. 28, 2009, Title of Invention: Apparatus for continuous fabrication of superconducting tapes).

### DISCLOSURE

### Technical Problem

The present invention is directed to providing a wire rod deposition system that can obtain excellent thin film quality as materials reach a surface of a wire rod and have a certain direction in a set area.

### Technical Solution

According to one aspect of the present invention, there is provided a wire rod deposition system including a plurality of roller parts around which a wire rod is wound to move and which are axially length-adjustable; a heater part heating the wire rod passing the roller parts; a cathode part providing a deposition material to the wire rod; and a cooling part cooling the wire rod.

The roller parts may each include a roller support part; a roller shaft part rotatably mounted on the roller support part; and a roller absorption part disposed between the roller support part and the roller shaft part and absorbing expansion of the roller shaft part.

The roller shaft part may include a pair of shaft rotation parts rotatably mounted on the roller support part and spaced apart from each other; a shaft connection part connecting the pair of shaft rotation parts; and a shaft coupling part coupling the shaft rotation parts and the shaft connection part to each other.

The roller parts may each further include one or more additional roller support parts disposed in a longitudinal direction of the shaft connection part and supporting the wire rod; and an additional roller absorption part disposed between the additional roller support parts and the shaft coupling part and absorbing expansion of the additional roller support parts.

The roller parts may each further include a roller discharge part discharging a gas remaining in the roller shaft part.

The roller parts may each further include a roller maintenance part disposed between the additional roller support parts and covering a space formed in the shaft connection part so that the additional roller support parts come into close contact with the additional roller absorption part.

The cooling part may be disposed between the heater part and the roller parts and may come into direct contact with the wire rod.

The wire rod deposition system according to the present invention may further include an adherence prevention part covering an outer side of the wire rod excluding a deposition space of the wire rod to prevent adherence of scattered particles thereto.

### Advantageous Effects

In a wire rod deposition system according to the present invention, a wire rod is heated by a heater part and is deposited by moving while wound around a plurality of roller parts, and the roller parts are axially length-adjustable even when heated by the heater part, and accordingly, it is possible to stably support the wire rod.

### DESCRIPTION OF DRAWINGS

FIG. 1 is a view schematically illustrating a wire rod deposition system according to one embodiment of the present invention.

FIG. 2 is a view schematically illustrating a roller part according to one embodiment of the present invention.

FIG. 3 is a view schematically illustrating a roller maintenance part according to one embodiment of the present invention.

FIG. 4 is a view schematically illustrating a cooling part according to one embodiment of the present invention.

FIG. 5 is a view schematically illustrating an adherence prevention part according to one embodiment of the present invention.

FIG. 6 is a view schematically illustrating a heater part according to a first embodiment of the present invention.

FIG. 7 is a view schematically illustrating a heater part according to a second embodiment of the present invention.

FIG. 8 is a view schematically illustrating a heater part according to a third embodiment of the present invention.

FIG. 9 is a view schematically illustrating a third lower heat dissipation part according to the third embodiment of the present invention.

FIG. 10 is a view schematically illustrating a cathode part according to one embodiment of the present invention.

### MODES OF THE INVENTION

Hereinafter, embodiments of a wire rod deposition system according to the present invention will be described with reference to the accompanying drawings. In this process, thicknesses of lines or sizes of components illustrated in the drawings may be exaggerated for clarity and convenience of description. Also, terms used below are terms defined in consideration of functions in the present invention and may be changed according to an intention or customary practice of a user or an operator. Therefore, the terms should be defined based on the content throughout the present specification.

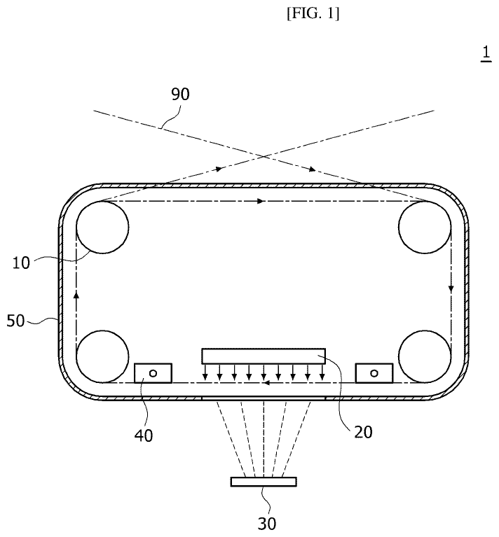

FIG. 1 is a view schematically illustrating a wire rod deposition system according to one embodiment of the present invention. Referring to FIG. 1, a wire rod deposition system 1 according to one embodiment of the present invention includes roller parts 10, a heater part 20, and a cathode part 30.

A wire rod 90 may be wound around two or more roller parts 10 and move. The roller parts 10 are axially length-adjustable and thus can prevent an operational failure even when heated by the heater part 20. For example, a pair of roller parts 10 may be disposed to face each other, or three or more roller parts 10 may be disposed. The wire rod 90 may be deposited by passing each of the roller parts 10 repeatedly multiple times.

The heater part 20 may heat the wire rod 90 passing the roller parts 10. For example, the heater part 20 may be disposed between the roller parts 10 and may heat the wire rod 90 from above the wire rod 90 passing the roller parts 10.

The cathode part 30 may provide a deposition material to the wire rod 90. For example, the roller parts 10, the heater part 20, and the cathode part 30 may be embedded in a chamber that can be transformed into a vacuum state. The cathode part 30 may include a cathode provision part embedded in the chamber and providing the deposition material, a cathode gas part supplying a gas to the chamber, and a cathode power part supplying power to the chamber.

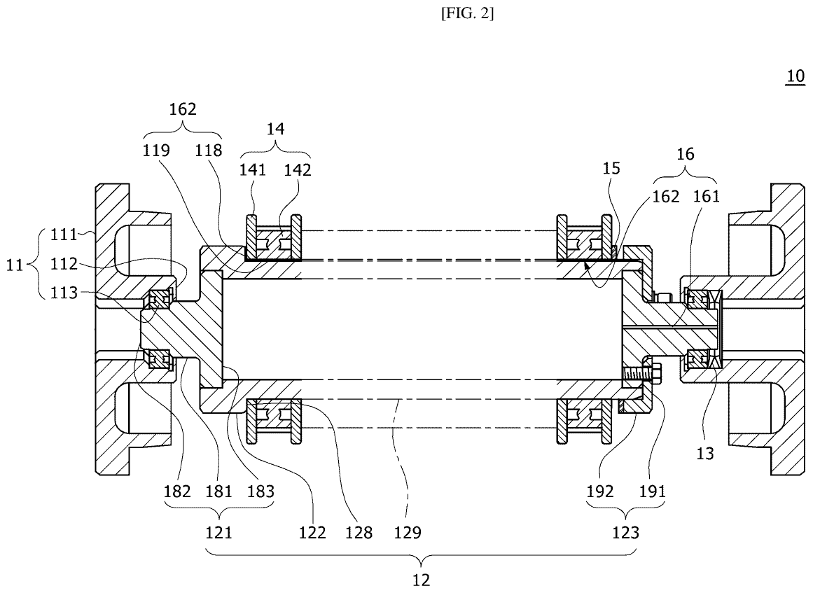

FIG. 2 is a view schematically illustrating a roller part according to one embodiment of the present invention. Referring to FIG. 2, the roller part 10 according to one embodiment of the present invention may include a roller support part 11, a roller shaft part 12, and a roller absorption part 13.

The roller support part 11 may be installed to be fixed to the chamber. For example, the roller support part 11 may include a pair of first roller support parts 111 installed to be fixed to the chamber and face each other and a second roller support part 112 formed on the first roller support parts 111 and into which the roller shaft part 12 is able to be inserted. The second roller support part 112 may form a hole at a central portion of the first roller support parts 111. A third roller support part 113 may be mounted on the second roller support part 112. The third roller support part 113 may be a bearing.

The roller shaft part 12 may be rotatably mounted on the roller support part 11. For example, the roller shaft part 12 may rotate while both ends thereof are inserted into the second roller support part 112 and supported by the third roller support part 113. The roller shaft part 12 may pass through the third roller support part 113. The roller shaft part 12 may be supported by the third roller support part 113 that is movable at the second roller support part 112.

The roller absorption part 13 may be disposed between the roller support part 11 and the roller shaft part 12 and may absorb expansion of the roller shaft part 12. For example, the roller absorption part 13 may be embedded in the second roller support part 112 and may support the roller shaft part 12. The roller shaft part 12 may pass through the roller absorption part 13. Due to the roller absorption part 13, a clearance may be formed in the second roller support part 112. When the roller shaft part 12 is heated and the length thereof expands, the roller absorption part 13 may contract. The roller absorption part 13 may come into close contact with the third roller support part 113.

More specifically, the roller shaft part 12 may include shaft rotation parts 121, a shaft connection part 122, and a shaft coupling part 123.

The shaft rotation parts 121 may be rotatably mounted on the roller support part 11. A pair of shaft rotation parts 121 may be spaced apart from each other and mounted on each roller support part 11. For example, the shaft rotation parts 121 may include a first shaft rotation part 181 that is inserted into the second roller support part 112 and caught at the third roller support part 113, a second shaft rotation part 182 that extends from one end of the first shaft rotation part 181 and is inserted into the third roller support part 113 and rotatably supported by the third roller support part 113, and a third shaft rotation part 183 that extends outward from the other end of the first shaft rotation part 181. The first shaft rotation part 181 and the second shaft rotation part 182 may each have a cylindrical shape. The third shaft rotation part 183 may be formed at an end of the first shaft rotation part 181 and may have a disc shape. A diameter of the third shaft rotation part 183 may be formed to be greater than a diameter of the first shaft rotation part 181. A diameter of the second shaft rotation part 182 may be formed to be less than the diameter of the first shaft rotation part 181.

The shaft connection part 122 may connect the pair of shaft rotation parts 121. For example, the shaft connection part 122 may have a hollow cylindrical shape and may have a step formed thereon so that both ends are caught and fixed at an edge of the second shaft rotation part 182.

The shaft coupling part 123 may couple the shaft rotation parts 121 and the shaft connection part 122 to each other. For example, the shaft coupling part 123 may include a first shaft coupling part 191 disposed to face the second shaft rotation part 182 and a second shaft coupling part 192 that is bent from the first shaft coupling part 191 and covers an end of the shaft connection part 122. The shaft coupling part 123 may be disposed at one end or both ends of the shaft connection part 122. The third shaft rotation part 183 may be bolt-coupled to the first shaft coupling part 191.

The wire rod 90 may be directly wound around an outer circumferential surface of the shaft connection part 122 and move. In addition, additional roller support parts 14 mounted on the shaft connection part 122 and around which the wire rod 90 is wound to move and an additional roller absorption part 15 maintaining a clearance of the shaft connection part 122 may be additionally mounted. When these are added, operability of the wire rod 90 may be ensured in a double bearing method.

One or more additional roller support parts 14 may be disposed in a longitudinal direction of the shaft connection part 122 and may support the wire rod 90. For example, the additional roller support parts 14 may each include a pair of first additional support parts 141 having a ring shape and a second additional support part 142 disposed between the first additional support parts 141. An outer diameter of the additional support part 141 is greater than an outer diameter of the second additional support part 142. As a result, when the wire rod 90 is seated on the second additional support part 142, the first additional support parts 141 disposed at both sides may prevent the wire rod 90 from deviating. The second additional support part 142 may be a bearing. The wire rod 90 may be seated on the second additional support part 142, and friction generated in a process in which the wire rod 90 moves may be suppressed. The additional roller support parts 14 may be disposed consecutively according to a width of the wire rod 90 or the number of times the wire rod 90 is wound around the roller parts 10. When the additional roller support parts 14 are disposed consecutively, the first additional support parts 141 and the second additional support parts 142 may be alternately disposed.

A shaft mounting part 129 may be formed on the outer circumferential surface of the shaft connection part 122. The shaft mounting part 129 may have the shape of a groove that is recessed to have an outer diameter less than an outer diameter of the shaft connection part 122. The shaft mounting part 129 may extend from a set point of the shaft connection part 122 to an end thereof, and the additional roller support parts 14 may be inserted from the end to the set point. At the set point, a shaft step part 128 may be formed so that the additional roller support parts 14 are caught and supported thereat.

The additional roller absorption part 15 may be disposed between the additional roller support parts 14 and the shaft coupling part 123 and may absorb expansion of the additional roller support parts 14. For example, the additional roller absorption part 15 may be disposed between the shaft coupling part 123 and the additional roller support part 14 disposed at an edge among the additional roller support parts 14 that are disposed consecutively. In addition, the additional roller absorption part 15 may be selectively disposed between the additional roller support parts 14 disposed in a row. That is, the additional roller absorption part 15 may be disposed between the pair of first additional support parts 141 facing each other.

The roller absorption part 13 and the additional roller absorption part 15 may be wave washers or disc springs. For example, the roller absorption part 13 and the additional roller absorption part 15 may be wave washers or disc springs. In addition, any one of the roller absorption part 13 and the additional roller absorption part 15 may be a wave washer, and the other one may be a disc spring. When the shaft connection part 122 expands, the roller absorption part 13 may contract and may secure a space for the expansion of the shaft connection part 122. When the additional roller support part 14 adjacent to the additional roller absorption part 15 expands, the additional roller absorption part 15 may contract and may secure a space for the expansion of the additional roller support part 14.

The roller parts 10 according to one embodiment of the present invention may each further include a roller discharge part 16. The roller discharge part 16 may discharge a gas remaining in the roller shaft part 12 without being discharged in a vacuum process.

For example, the roller discharge part 16 may include a first discharge part 161 discharging a gas remaining in the shaft connection part 122 and a second discharge part 162 discharging a gas remaining between the shaft connection part 122 and the additional roller support part 14.

The first discharge part 161 may have the shape of a hole that passes through the first shaft rotation part 181 and the second shaft rotation part 182. In addition, the first discharge part 161 may have the shape of a hole that passes through the third shaft rotation part 183 and the first shaft coupling part 191. The first discharge part 161 may discharge the gas inside the shaft connection part 122.

The second discharge part 162 may include a second discharge mounting groove part 119 forming a groove for movement of a gas in a longitudinal direction of the shaft mounting part 129 and a second discharge step groove part 118 formed on the shaft step part 128 and communicating with the second discharge mounting groove part 119. A plurality of second discharge parts 162 may be formed in a circumferential direction of the shaft mounting part 129.

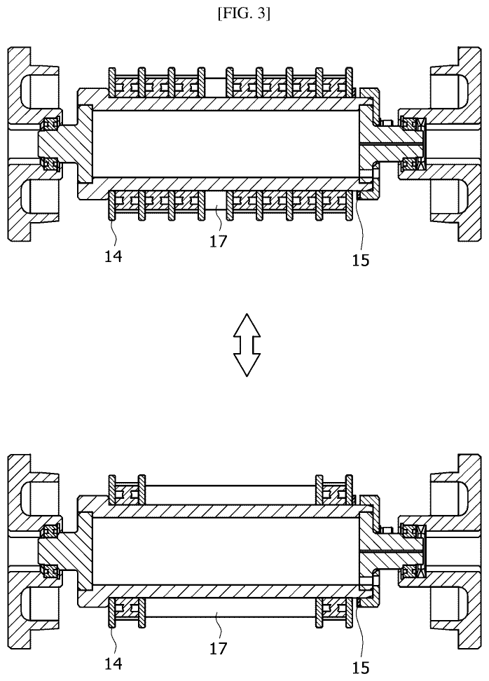

FIG. 3 is a view schematically illustrating a roller maintenance part according to one embodiment of the present invention. Referring to FIG. 3, the roller parts 10 according to one embodiment of the present invention may each further include a roller maintenance part 17.

The roller maintenance part 17 may be disposed between the additional roller support parts 14 and may cover a space formed in the shaft connection part 122 so that the additional roller support parts 14 come into close contact with the additional roller absorption part 15. For example, the number of additional roller support parts 14 may vary according to the work environment, and when the number of installed additional roller support parts 14 decreases, a remaining space may be covered by the roller maintenance part 17. That is, when four additional roller support parts 14 are used at first and two additional roller support parts 14 are used afterwards, the roller maintenance part 17 corresponding to the two additional roller support parts 14 is mounted on the shaft connection part 122. As a result, the additional roller support parts 14 and the additional roller absorption part 15 may remain in close contact with each other.

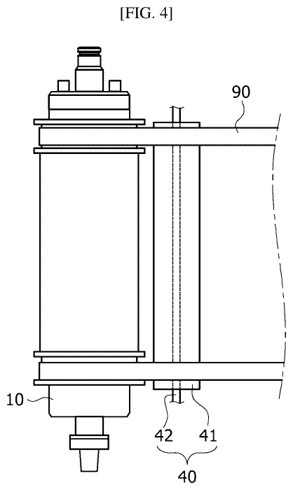

FIG. 4 is a view schematically illustrating a cooling part according to one embodiment of the present invention. Referring to FIGS. 1 and 4, the wire rod deposition system 1 according to one embodiment of the present invention may further include a cooling part 40. The cooling part 40 may cool the wire rod 90. The cooling part 40 may cool the wire rod 90 heated by the heater part 20, thereby suppressing the roller parts 10 from being heated due to the wire rod 90. The cooling part 40 may be disposed between the heater part 20 and the roller parts 10 and may come into direct contact with the wire rod 90. For example, the cooling part 40 may include a cooling block part 41 installed to be fixed to the chamber and coming into contact with the wire rod 90 and a cooling circulation part 42 circulating cooling water to the cooling block part 41 to cool the cooling block part 41. The cooling part 40 may be additionally disposed between the heater part 20 and the roller part 10 that guides the wire rod 90 that has not passed the heater part 20 and may cool the wire rod 90. The cooling circulation part 42 may supply cooling water additionally to the roller parts 10 and directly cool the roller parts 10.

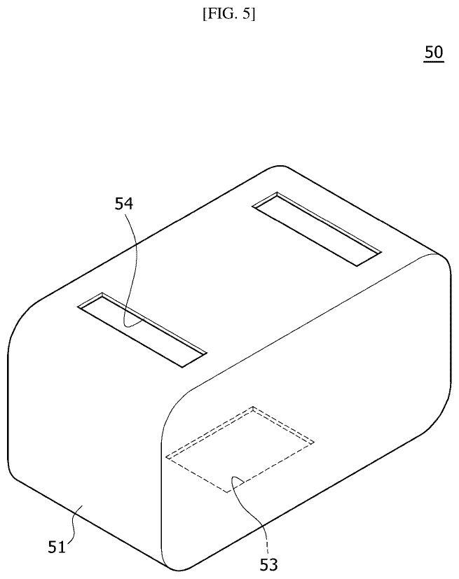

FIG. 5 is a view schematically illustrating an adherence prevention part according to one embodiment of the present invention. Referring to FIGS. 1 and 5, the wire rod deposition system 1 according to one embodiment of the present invention may further include an adherence prevention part 50.

The adherence prevention part 50 may cover an outer side of the wire rod 90 excluding a deposition space of the wire rod 90 to prevent adherence of scattered particles to the wire rod 90 except for the deposition space. For example, the adherence prevention part 50 may include a prevention box part 51 having the shape of a box surrounding the roller parts 10 and the heater part 20. A prevention deposition hole part 53 for deposition may be formed at a lower portion of the prevention box part 51, and a prevention passage hole part 54 for passage of the wire rod 90 may be formed at an upper portion of the prevention box part 51. The prevention box part 51 may be able to be disassembled and assembled and may be installed to be fixed to the chamber through a separate support fixture.

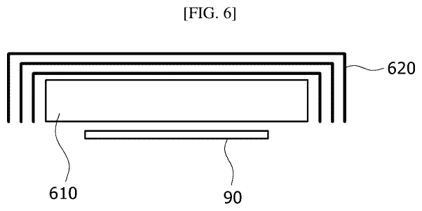

FIG. 6 is a view schematically illustrating a heater part according to a first embodiment of the present invention. Referring to FIG. 6, a heater part 20 according to a first embodiment of the present invention may include a first heater part 610 and a first heat dissipation part 620.

The first heater part 610 may be disposed above the wire rod 90 and may be heated when power is applied thereto. A sheath heater, a ceramic mold heater, or a positive temperature coefficient (PTC) heater may be used as the first heater part 610.

One or more first heat dissipation parts 620 may cover the first heater part 610 so that only a lower portion of the first heater part 610 is open and may discharge heat. The first heat dissipation parts 620 may cover the first heater part 610 so that the wire rod 90 passing a bottom of the first heater part 610 is intensively heated and may block transfer of radiant heat to the periphery of the first heater part 610.

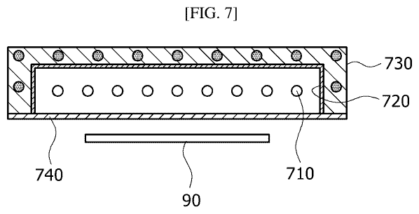

FIG. 7 is a view schematically illustrating a heater part according to a second embodiment of the present invention. Referring to FIG. 7, a heater part 20 according to a second embodiment of the present invention may include a second heater part 710, a second reflecting part 720, and a second cooling part 730.

The second heater part 710 may be disposed above the wire rod 90 and may be heated by a lamp being turned on when power is applied thereto. For example, a halogen lamp may be used as the second heater part 710. A plurality of second heater parts 710 may be disposed across a top of the wire rod 90.

The second reflecting part 720 may cover the second heater part 710 so that only a lower portion of the second heater part 710 is open. The second reflecting part 720 may reflect heat generated from the second heater part 710. The second heater part 710 may be mounted on the second reflecting part 720. In addition, the second heater part 710 may be mounted on the second cooling part 730.

The second cooling part 730 may come into contact with the second reflecting part 720 and may cool the second reflecting part 720 by cooling water moved thereto. The second cooling part 730 may be installed to be fixed to the chamber by a separate fixer. The second reflecting part 720 may be attached to or coated on an inner wall of the second cooling part 730. An infrared reflector coated with gold may be used as the second reflecting part 720 on the inner wall of the second cooling part 730.

In addition, a second transmitting part 740 may cover a lower portion of the second cooling part 730 and may transmit heat generated from the second heater part 710.

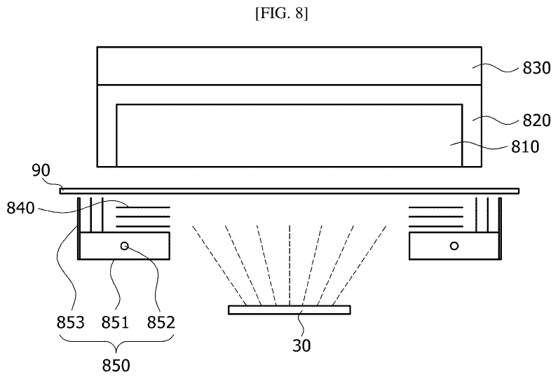

FIG. 8 is a view schematically illustrating a heater part according to a third embodiment of the present invention. Referring to FIG. 8, a heater part 20 according to a third embodiment of the present invention may include a third upper heater part 810, a third upper reflecting part 820, a third upper cooling part 830, a third lower heat dissipation part 840, and a third lower cooling part 850.

The third upper heater part 810 may be disposed above the wire rod 90 and may generate heat. For example, the first heater part 610 of FIG. 6 or the second heater part 710 of FIG. 7 may be used as the third upper heater part 810, and various heaters for heating the wire rod 90 may be applied thereto.

The third upper reflecting part 820 may cover the third upper heater part 810 to open only a lower portion of the third upper heater part 810. The third upper reflecting part 820 may reflect heat generated from the third upper heater part 810. The third upper heater part 810 may be mounted on the third upper reflecting part 820. The third upper heater part 810 may be mounted on the third upper cooling part 830.

The third upper cooling part 830 may come into contact with the third upper reflecting part 820 and may cool the third upper reflecting part 820 by cooling water moved thereto. The third upper cooling part 830 may be installed to be fixed to the chamber by a separate fixer. The third upper reflecting part 820 may be attached to or coated on an inner wall of the third upper cooling part 830.

The third lower heat dissipation part 840 may be disposed between the wire rod 90 and the cathode part 30 and may induce heat to be concentrated on the wire rod 90. For example, a plurality of third lower heat dissipation parts 840 may be stacked, and heat may be transferred to the wire rod 90 as the wire rod 90 passes the stacked third lower heat dissipation parts 840. The third lower heat dissipation parts 840 may suppress radiant heat caused by the third upper heater part 810 from being transferred to peripheral equipment.

The third lower cooling part 850 may cool the third lower heat dissipation part 840. For example, heat transferred through the third lower heat dissipation part 840 may be cooled through the third lower cooling part 850. The third lower cooling part 850 may have a hole formed in a central portion and may be disposed to face the third upper heater part 810, the wire rod 90, and the cathode part 30 in a vertical line. The third lower cooling part 850 may include a lower cooling block part 851, a lower cooling circulation part 852 inducing circulation of cooling water to the lower cooling block part 851, and a lower cooling partition part 853 coupled to an edge of the lower cooling block part 851.

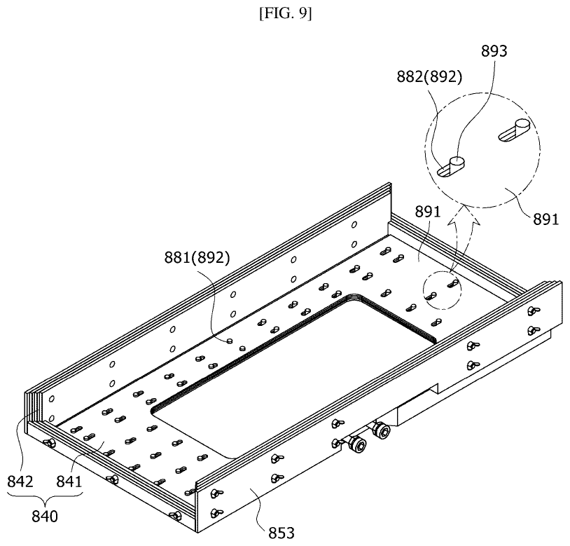

FIG. 9 is a view schematically illustrating a third lower heat dissipation part according to the third embodiment of the present invention. Referring to FIG. 9, the third lower heat dissipation part 840 according to the third embodiment of the present invention may include a heat dissipation center part 841 and a heat dissipation side part 842.

A plurality of heat dissipation center parts 841 may each have a through-hole part 849 formed in a central portion and may be stacked on the third lower cooling part 850. For example, the heat dissipation center parts 841 may be stacked on the lower cooling block part 851 in the vertical direction.

A plurality of heat dissipation side parts 842 may cover edges of the heat dissipation center parts 841. For example, the plurality of heat dissipation side parts 842 disposed in the horizontal direction may come into close contact with the lower cooling partition part 853 and may be installed to be fixed to the lower cooling partition part 853 by a fixer.

More specifically, the heat dissipation center parts 841 may each include a center plate part 891, a center fixing hole part 892, and a center support part 893.

The center plate part 891 may have the through-hole part 849 formed in a central portion. For example, a plurality of center plate parts 891 may each have the shape of a rectangular plate and may be stacked on the lower cooling block part 851.

The center fixing hole part 892 may be formed in each of the center plate parts 891. For example, the center fixing hole part 892 may include a first fixing hole part 881 disposed in the central portion of the center plate part 891 having the shape of a rectangular plate and a second fixing hole part 882 disposed in both left and right sides of the first fixing hole part 881.

The center support part 893 may pass through the center fixing hole part 892, may be mounted on the third lower cooling part 850, and may support the center plate part 891. For example, the center support part 893 may be a pin, a bolt, etc., that is mounted on the lower cooling block part 851 and protrudes upward, and a nut may be selectively coupled thereto to fix the center plate part 891.

The center support part 893 may fix the central portion of the center plate part 891, and the center fixing hole part 892 may have the shape of a rectangular hole whose length gradually increases from the central portion of the center plate part 891 toward an end thereof. For example, the first fixing hole part 881 may have a size that corresponds to the center support part 893, and the central portion of the center plate part 891 in which the first fixing hole part 881 is formed may be fixed by the center support part 893. A plurality of second fixing hole parts 882 may be formed in both left and right sides of the first fixing hole part 881. A length of a rectangular hole of the second fixing hole part 882 may gradually increase from the first fixing hole part 881 toward both left and right ends of the center plate part 891. As a result, interference with the center support part 893 may be prevented even when the center plate part 891 is heated and expands.

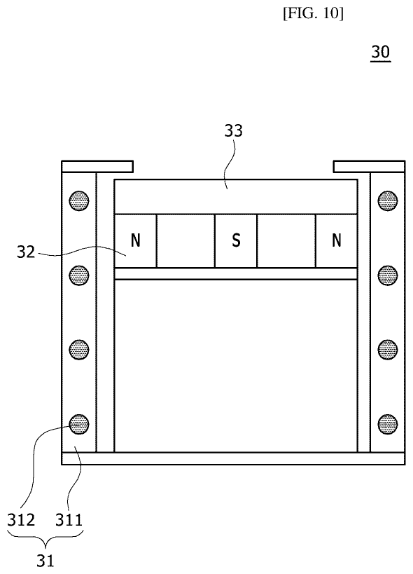

FIG. 10 is a view schematically illustrating a cathode part according to one embodiment of the present invention. Referring to FIG. 10, the cathode part 30 according to one embodiment of the present invention may include a cathode cooling part 31, a cathode magnet part 32, and a cathode material part 33.

At the cathode cooling part 31, a cathode flow path part 312 may be formed in a cathode block part 311, and cooling water may circulate. At this time, the cathode flow path part 312 may be integrally formed with the cathode block part 311 by a gun-drill technique and a welding process and may improve thermal conductivity.

The cathode cooling part 31 may have a shape with an open upper side, the cathode magnet part 32 may be embedded in the cathode cooling part 31 and may provide a magnetic force, and the cathode material part 33 may be exposed to the outside through an upper surface of the cathode magnet part 32 and may provide a deposition material.

An operation of the wire rod deposition system according to one embodiment of the present invention that has the above-described structure will be described below.

The wire rod 90 fed to the chamber is moved by being wound multiple times around the plurality of roller parts 10, the wire rod 90 disposed between the roller parts 10 is heated by the heater part 20, and a material provided from the cathode part 30 is deposited on the wire rod 90.

When the roller parts 10 are heated by the heater part 20, the roller shaft part 12 expands, and the roller absorption part 13 contracts and supports the expanded roller shaft part 12. When the additional roller support part 14 expands, the additional roller absorption part 15 contracts and supports the expanded additional roller support part 14. At this time, the roller shaft part 12 and the additional roller support part 14 surrounding the roller shaft part 12 may each have a bearing provided thereon to ensure the operability of the wire rod 90.

The roller discharge part 16 may induce a gas remaining in the roller parts 10 to be stably discharged, and the roller maintenance part 17 may replace a space from which the additional roller support part 14 is omitted depending on the work environment.

The heater part 20 is disposed above the wire rod 90 and adopts a heat dissipating and reflecting structure to supply heat intensively to the wire rod 90 moving below the heater part 20 and to suppress transfer of radiant heat to other equipment. For example, the plurality of third lower heat dissipation parts 840 are designed to be stacked. The plurality of third lower heat dissipation parts 840 each have a fixed central portion, and a length of the center fixing hole part 892 formed in the third lower heat dissipation part 840 gradually increases from a central portion of the third lower heat dissipation part 840 toward an edge thereof. As a result, even when the third lower heat dissipation part 840 expands due to high-temperature heat of the third upper heater part 810, a mounting state can be stably maintained. The heater part 20 may be disposed below or beside the wire rod 90.

The cooling part 40 is disposed between the roller parts 10 and the heater part 20 and comes into direct contact with the heated wire rod 90 to cool the wire rod 90, and in this way, the cooling part 40 can prevent overheating of the roller parts 10 around which the wire rod 90 is wound. The cooling part 40 may be disposed on both left and right sides of the heater part 20, and when needed, cooling water of the cooling part 40 may pass the roller parts 10 to directly cool the roller parts 10.

The adherence prevention part 50 is disposed to surround the entire outer side of the wire rod 90 except for the deposition space of the wire rod 90. As a result, evaporated particles scattered from the cathode part 30 are prevented from being attached to the wire rod 90 in an area except for the deposition space.

In the wire rod deposition system 1 according to one embodiment of the present invention, the wire rod 90 may be heated by the heater part 20 and may be deposited by moving while wound around the plurality of roller parts 10. The roller parts 10 are axially length-adjustable even when heated by the heater part 20, and accordingly, it is possible to stably support the wire rod.

Although the present invention has been described above with reference to the embodiments illustrated in the drawings, the description is merely illustrative, and those of ordinary skill in the art should understand that various modifications and other equivalent embodiments are possible therefrom. Therefore, the true technical protection scope of the present invention should be defined by the claims below.

1. A wire rod deposition system comprising:
a plurality of roller parts around which a wire rod is wound to move and which are axially length-adjustable;
a heater part heating the wire rod passing the roller parts;
a cathode part providing a deposition material to the wire rod; and
a cooling part cooling the wire rod.

2. The wire rod deposition system of claim 1, wherein the roller parts each include:
a roller support part;
a roller shaft part rotatably mounted on the roller support part; and
a roller absorption part disposed between the roller support part and the roller shaft part and absorbing expansion of the roller shaft part.

3. The wire rod deposition system of claim 2, wherein the roller shaft part includes:
a pair of shaft rotation parts rotatably mounted on the roller support part and spaced apart from each other;
a shaft connection part connecting the pair of shaft rotation parts; and
a shaft coupling part coupling the shaft rotation parts and the shaft connection part to each other.

4. The wire rod deposition system of claim 3, wherein the roller parts each further include:
one or more additional roller support parts disposed in a longitudinal direction of the shaft connection part and supporting the wire rod; and
an additional roller absorption part disposed between the additional roller support parts and the shaft coupling part and absorbing expansion of the additional roller support parts.

5. The wire rod deposition system of claim 4, wherein the roller parts each further include a roller discharge part discharging a gas remaining in the roller shaft part.

6. The wire rod deposition system of claim 4, wherein the roller parts each further include a roller maintenance part disposed between the additional roller support parts and covering a space formed in the shaft connection part so that the additional roller support parts come into close contact with the additional roller absorption part.

7. The wire rod deposition system of claim 1, wherein the cooling part is disposed between the heater part and the roller parts and comes into direct contact with the wire rod.

8. The wire rod deposition system of claim 1, further comprising an adherence prevention part covering an outer side of the wire rod excluding a deposition space of the wire rod to prevent adherence of scattered particles thereto.
